(19) United States
(12) Patent Application Publication
(10) Pub. No.: US 2007/0288816 A1
(43) Pub. Date: Dec. 13, 2007

(54) Semiconductor integrated circuit and test method therefor

(75) Inventor: Osamu Nakanishi, Kanagawa (JP)

Correspondence Address: FOLEY AND LARDNER LLP;SUITE 500, 3000 K STREET NW, WASHINGTON, DC, 20007, US

(73) Assignee: NEC Electronics Corporation

(21) Appl. No.: 11/715,450

(22) Filed: Mar. 8, 2007

(30) Foreign Application Priority Data
Mar. 29, 2006 (JP) 2006-091637

(51) Int. Cl. G01R 31/28

(52) U.S. Cl. 714/724

(57) ABSTRACT

A semiconductor integrated circuit includes a logic circuit unit having a logic circuit and a first scan chain including a first scan chain to perform a scan chain for the logic circuit, and a memory unit having a memory, a BIST circuit, and a second scan chain to perform a scan test therefor. The two scan chains form a scan chain, and the first scan chain is disposed in an output side of the second scan chain. At a burn-in, along with setting the first scan chain to enable according to a scan enable signal, the second scan chain is set to disenable according to the scan enable signal and a memory test start signal, and stress is applied at the same time to the user logic circuit by a scan test and to the memory by a BIST.

### BACKGROUND OF THE INVENTION

1. Field of the Invention

The present invention relates a semiconductor apparatus having a scan chain for a scan test in a self-checking and a user logic circuit of a memory and a test method therefor, and particularly to a semiconductor integrated circuit and a test method therefor that are purposed to improve the efficiency in executing burn-in test.

2. Description of Related Art

A burn-in test for a semiconductor integrated circuit is a test to be performed to a packaged finished product, and also is an accelerated test for burn-in stress during a function test in order to remove an initial failure. After burning in, an electric characteristic test and an appearance structure check are performed to eliminate defective products, and reliability tests including an environmental and a lifetime test are performed to be shipped.

With increasing size of semiconductor integrated circuit in recent years, a plurality of functional blocks are integrated in one chip and an importance of the reliability tests including a burn-in is increasing. However, to test a semiconductor integrated circuit integrating a large-scale logic circuit and a memory such as a DRAM (Dynamic Random Access Memory) or a SRAM (Static Random Access Memory), it is difficult to completely realize a condition that the semiconductor integrated circuit operates on a set device. Therefore, in a consumption current and a burn-in test or the like, stress is applied to a circuit by a scan test. Further, for a memory having a BIST function, a method is used to give stress to the memory by starting up a memory BIST at a burn-in test.

By the way, a memory BIST is scan designed to perform a scan test the memory BIST. FIG. 4 is a view showing a scan chain in a conventional semiconductor integrated circuit 100. It is usually connected irrelevantly whether it is a scan FF 111a of a user logic circuit 110 or a scan FF 121a of a memory BIST circuit 120 to form a scan chain 130. By scan designing the memory BIST circuit 120 in this way, a failure detection rate can be improved. In this case, by applying stress to the user logic circuit 100 using a scan test, the memory BIST circuit 120 cannot be used. Accordingly a burn-in has two processes; one is to toggle the user logic circuit 100 by a scan test to give stress and burn-in, and another is to toggle the memory 140 by the BIST circuit 120 to give stress and burn-in. Specifically, when burning in, stress must be applied by executing chronologically a scan test by the scan chain 130 and a memory test by the memory BIST circuit, thereby requiring a long test time.

Therefore, the memory BIST circuit 120 can be designed not to be scan designed. As shown in FIG. 5, by implementing the scan chain 111 only in the user logic circuit 110, it is possible to apply stress to the memory 140 by the memory BIST circuit 120 in parallel with applying stress to the user logic circuit 110 by the scan chain 111, thereby reducing the burn-in test time. However as the scan test cannot be performed to the memory BIST circuit 120, the failure detection rate of the memory BIST circuit 120 decreases.

Thus a semiconductor integrated circuit that is possible to perform a burn-in by applying stress at the same time to the memory and logic portions even when scan designing the memory BIST is disclosed in Japanese Unexamined Patent Application Publication No. 2005-24410 (Yamashita). FIG. 6 is a block diagram showing a semiconductor integrated circuit disclosed by Yamashita.

In a semiconductor integrated circuit integrating a SRAM and a logic circuit, a pass/fail signal is output from an output terminal as a test result, where the pass/fail signal is a signal output from the BIST circuit 215. Accordingly if a data comparing circuit broke down, it is possible to incorrectly recognize a non-defective/defective product. Therefore, the BIST circuit 215 is a logic circuit to be scan tested. A scan flip-flop 224 inside the BIST circuit 215 is connected to a scan chain 221 is connected from a scan flip-flop 223 outside the BIST circuit 215, and also is connected to a scan flip-flop 225 outside the BIST circuit 215 via the scan flip 224 inside the BIST circuit 215.

Thus normally as the BIST circuit 215 is scanned while executing a scan test, a scan test and a memory BIST cannot be performed at the same time and stress cannot be applied at the same time over the device. The semiconductor integrated circuit disclosed by Yamashita further includes a bypass circuit that is constituted of a bypass line 222 and a selector 226, that excludes the scan flip-flop 224 inside the BIST circuit 215 from a scan test in a burn-in mode.

In the burn-in test, it is controlled to select an output from the bypass line 222 as an output from the selector 226 that is included in the bypass circuit by a burn-in mode control signal 210 so as to test excluding the flip-flop 224 inside the BIST circuit 215. This excludes the flip-flop 224 that is included in the BIST circuit 215 in the burn-in mode, a clock input for memory BIST is selected as an output from the selector 227 by a BIST mode control signal 220, and the clock signal is supplied at the same time to the SRAM 213 and memory BIST circuit 215. At the same time, a scan test signal is supplied to a logic unit.

By configuring to enable to perform a scan test and a memory BIST at the same time in the burn-in mode, it is possible to efficiently apply burn-in stress to over the device and the burn-in time can be reduced.

However in the semiconductor integrated circuit disclosed by Yamashita, a bypass circuit including a bypass line 222 and a selector 226 needs to be provided to the scan chain. A scan chain is formed regardless of whether the scan chain in the logic circuit or the scan FF in the memory BIST circuit. Thus practically the scan FF in the logic circuit and the scan FF in the memory BIST circuit cannot easily be separated. Specifically, as long as the design of scan chain in a semiconductor integrated circuit is not changed, there is no guarantee that scan FFs in the memory BIST circuit are connected in series. For example in an example of FIG. 4, a scan FFs inside the BIST circuit are not connected in series and two bypass circuits are required. In a method that provides a bypass circuit, a design for disposing a scan chain and the bypass circuit are complicated.

### SUMMARY OF THE INVENTION

According to an aspect of the present invention, there is provided a semiconductor integrated circuit that includes a logic circuit unit having a logic circuit and a first scan chain to perform a scan chain for the logic circuit, and a memory unit having a memory, a self-checking circuit for the memory, and a second scan chain to perform a scan test for the self-checking circuit. A scan chain is formed by the first and the second scan chains, and the second scan chain is disposed in an output side of the scan chain, and along with setting the first scan chain to enable according to one or a plurality of control signals, the second scan chain can be set to disenable.

In the present invention, as the second scan chain is disposed to an output side of a first scan chain, it is possible to test the memory by a self-checking circuit by disenabling the second scan chain while executing a scan test for the logic circuit by enabling the first scan chain. This enables to apply stress at the same time to the logic circuit and memory, thereby enabling to burn-in at the same time for the logic circuit and the memory and shortening the burn-in processes.

Specifically, the present invention provides a semiconductor integrated circuit and a test method therefor that are able to apply stress at the same time to a logic circuit and a memory with a simple configuration.

### BRIEF DESCRIPTION OF THE DRAWINGS

The above and other objects, advantages and features of the present invention will be more apparent from the following description taken in conjunction with the accompanying drawings, in which:

FIG. 1 is a schematic diagram showing a semiconductor integrated circuit according to an embodiment of the present invention;

FIG. 2 is a view explaining a stress apply method at a burn-in using a scan shift operation;

FIG. 3 is a view showing a part for a mode control of a scan chain in the memory BIST of a semiconductor integrated circuit 1;

FIG. 4 is a view showing a scan chain in a conventional semiconductor integrated circuit;

FIG. 5 is a view showing another scan chain in a conventional semiconductor integrated circuit; and

FIG. 6 is a block diagram showing a semiconductor integrated circuit disclosed by Yamashita.

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

This embodiment is a semiconductor integrated circuit integrating a user logic circuit and a memory with a memory BIST function, and the present invention is applied to a semiconductor integrated circuit that is able to perform a burn-in test by applying stress at the same time to the memory to the user logic circuit even if the user logic and the memory BIST circuits are scan designed.

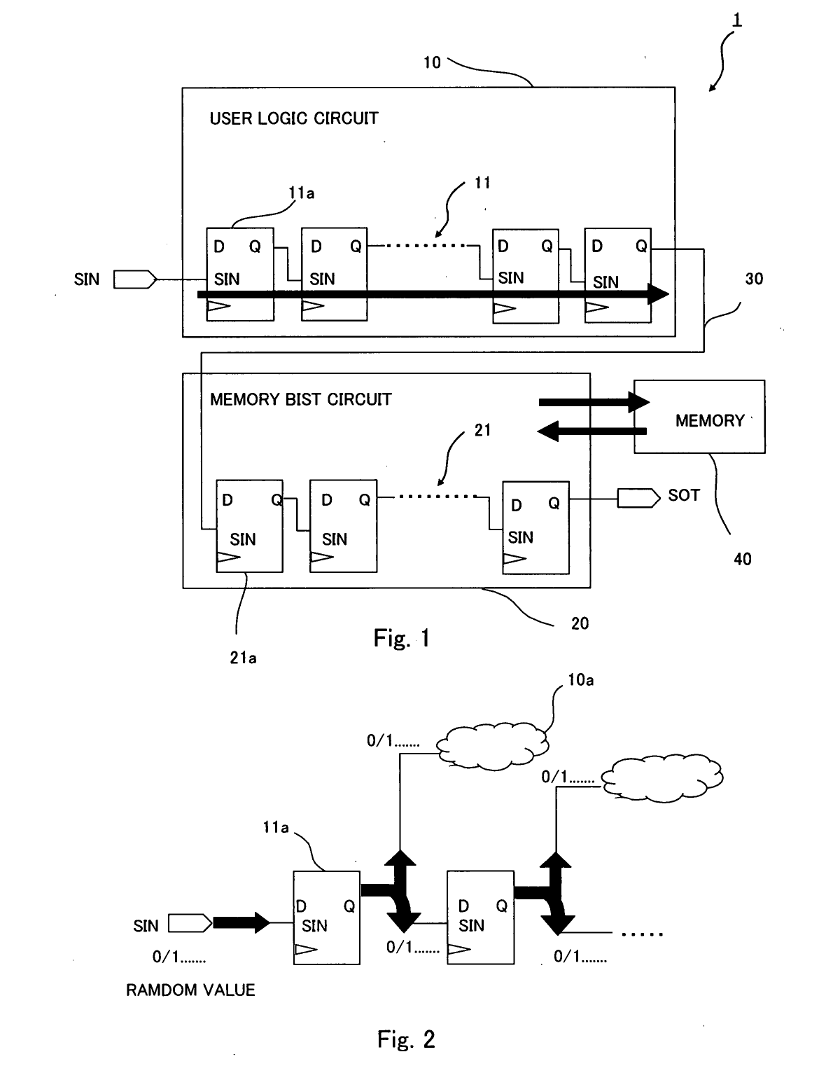

FIG. 1 is a schematic diagram showing a semiconductor integrated circuit according to an embodiment of the present invention. A semiconductor integrated circuit 1 includes a user logic circuit (logic circuit unit) 10 and a memory BIST circuit (memory unit) 20. The user logic circuit 10 and memory BIST circuit 20 includes one scan chain 30. In this example, the semiconductor integrated circuit 1 of this embodiment has a configuration in which a scan chain 21 inside the memory BIST circuit 20 is disposed in a last stage of a scan chain 11 in the user logic circuit 10 in the scan chain 30. Therefore, a scan flip-flop (scan FF) 21a of the memory BIST circuit 20 is connected to a scan out SOT. By this scan chain 30, the logic units of the user logic circuit 10 and the memory BIST circuit 20 are configured so that a scan test can be performed thereto.

Here, in the scan chain 30, by disposing the scan chain 21 of the memory BIST circuit 20 to an output side, the scan FFs after the scan FF 21a in the memory BIST circuit 20 can be set to a mode not used for a scan test. When performing a scan test for the user logic circuit 10 by enabling the scan FFs before the scan FF 21a in the memory BIST circuit 30, the scan chain 21 in the memory BIST circuit 20 is disenabled. This enables the memory BIST circuit 20 to perform a BIST operation to apply stress to the memory 40.

In this case, an output cannot be obtained from the scan out SOT. However at a burn-in, stress may only be applied in parallel to the user logic circuit 10 and memory 40 and the scan out needs not to be observed. Thus it does not matter whether the output cannot be obtained from the scan out SOT.

A stress apply method at a burn-in using a scan shift operation by the scan chain 11 is described hereinafter in detail. As shown in FIG. 2, a random value of 0 or 1 is input from a scan in SIN. Further, by a shift operation to the random value using the scan FF 11a, it is possible to toggle a logic unit 10a to be tested and is scan designed. This enables to apply stress to the user logic circuit at a burn-in that is scan designed.

At a burn-in, as a method to set only the scan chain 21 of the memory BIST circuit 30 to disenable, there is a simple method that inputs a scan enable signal separately to the scan chain 11 in the user logic circuit 10 and the scan chain 21 in the memory BIST circuit 20. Further at a burn-in, the scan chain 11 in the user logic circuit is set to enable. At this time, at the same time as setting the scan chain 21 in the memory BIST circuit 20 to disenable, a BIST is executed by the memory BIST circuit 20. This enables to apply stress at the same time to the user logic circuit 10 and memory 40 at a burn-in.

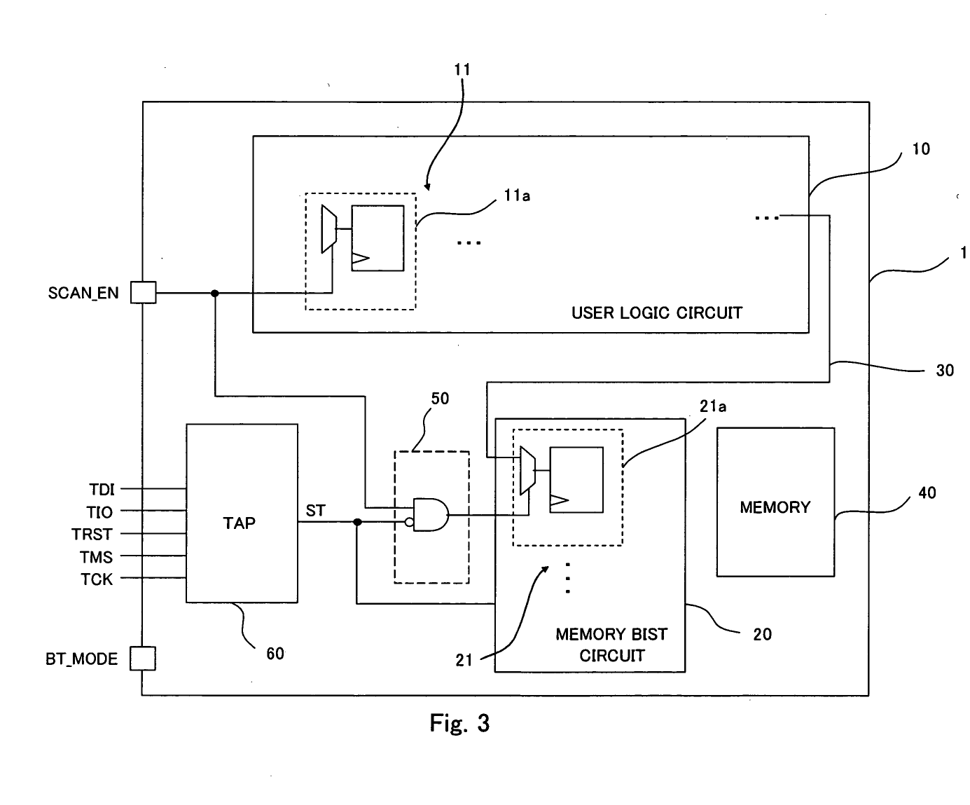

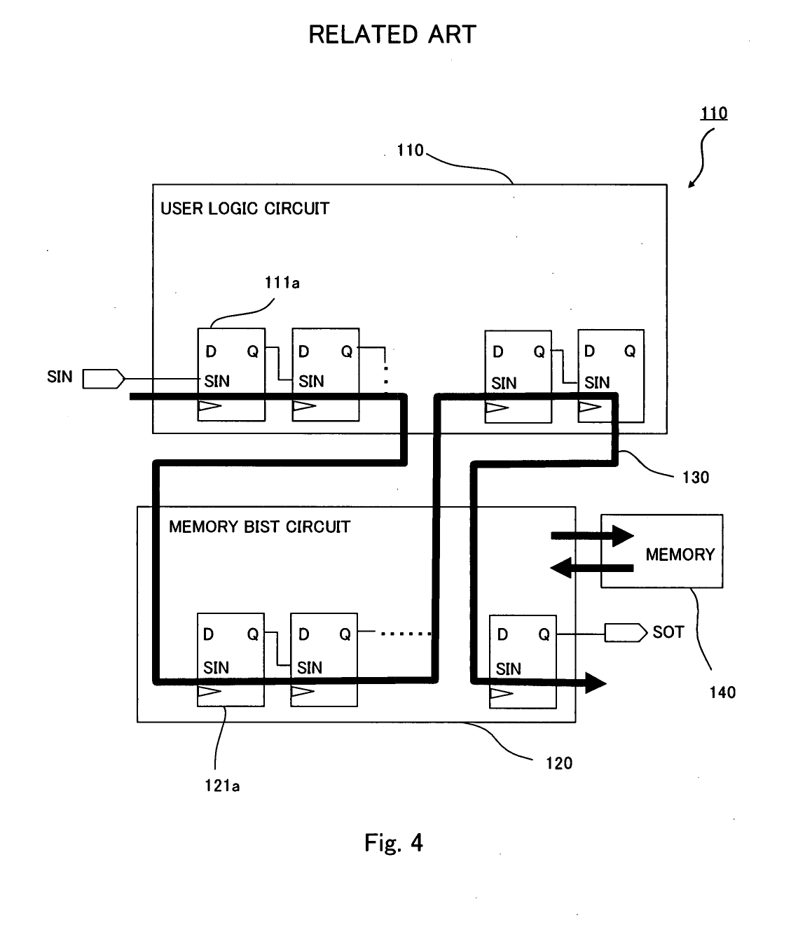

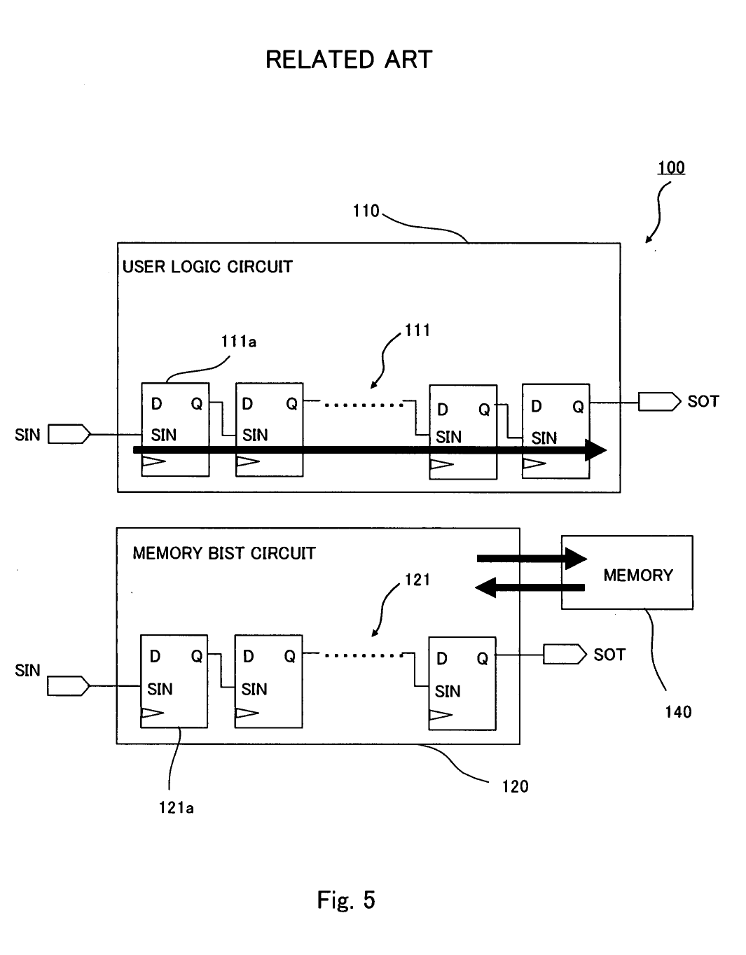

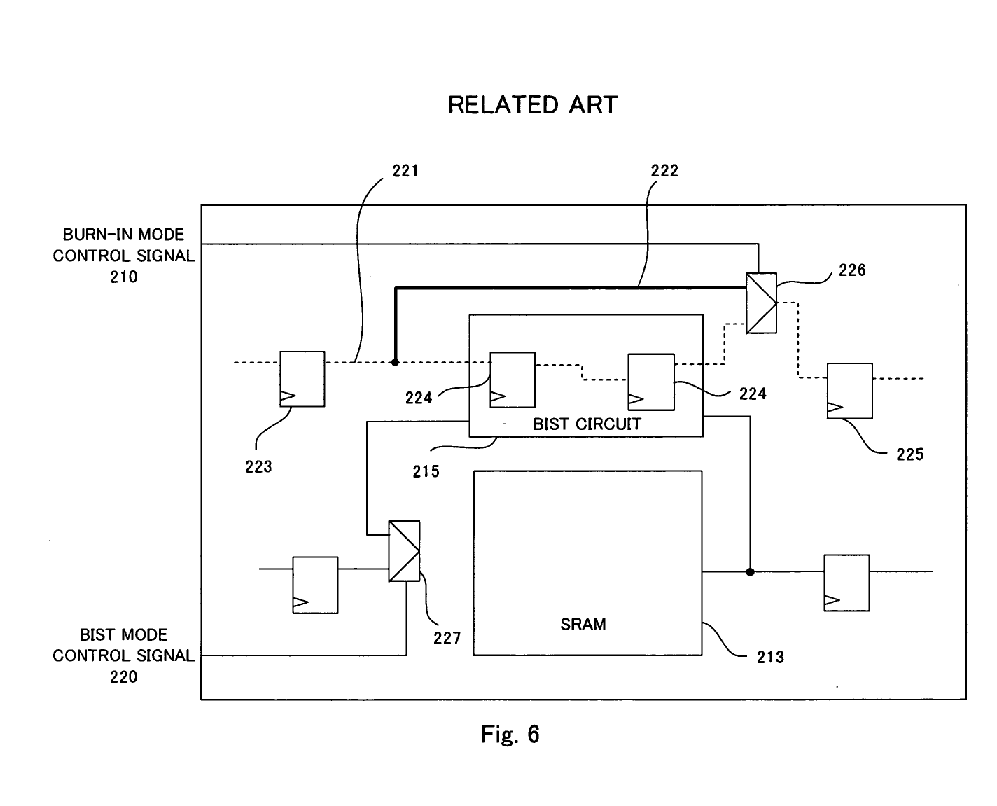

Another control method of a scan chain in the memory BIST circuit 20 at a burn-in is described hereinafter in detail. FIG. 3 is a view showing a part for a mode control of a scan chain in the memory BIST of the semiconductor integrated circuit 1. The semiconductor integrated circuit 1 includes a control unit 50 that enables the scan chain 11 in the user logic circuit 10 at the same time as disenabling the scan chain 21 in the BIST circuit 20 that is disposed in an output side thereof.

For example the control unit 50 can be configured by an AND circuit that inputs a scan enable signal for enabling the scan chain 30 and an inverted input signal of a memory test start signal ST for performing a BIST by the memory BIST circuit 20. In a burn-in, by setting the scan chain 11 in the user logic circuit 10 to enable by a scan enable signal SCAN_EN along with inputting an output from the AND circuit of the control unit 50 into the scan chain 21, the scan chain 21 is set to disenable. At this time, the memory test start signal ST is input to the memory BIST circuit 20 to let the memory BIST circuit 20 to start the BIST. This makes the scan chain to perform a scan test for the user logic circuit 10 and the BIST circuit 20 to perform a BIST for the memory 40, and applies stress at the same time to the user logic circuit 10 and the memory 40.

A Test Access Port (TAP) 60 is a port for accessing external to test by a boundary scan. The TAP 60 is an interface including 5 terminals of; a test data input TDI, a test data output TDO, a test reset (TRST), a test mode selection (TMS), and a test clock (TCK). The TAP 60 inputs/outputs and controls test data of the boundary scan test. The test data input TDI shifts the test data to a TAP controller. The test data output TDO is used to shift the test data output from the TAP controller. The test reset (TRST) is used as an option to drive the TAP controller to a test logic reset state when asserted, as a control terminal. The test mode selection (TMS) is used to change the state of the TAP controller. The test clock (TCK) is used to provide a clock to the TAP controller.

In this embodiment, the start of a BIST by the memory BIST circuit 20 is controlled by supplying a memory test start signal by the TAP 60 to the control unit 50 and the memory BIST circuit 20. Note that the start of the BIST may be controlled by anything other than the TAP.

A burn-in test mode signal BT_MODE that sets a circuit to a mode for a burn-in test may be used, for example to switch an input to the user logic circuit to a random pattern generation circuit. The control unit 50 may be an AND circuit that inputs a scan enable signal and a burn-in test mode BT_MODE. In either case, by providing the control unit 50, a control terminal to control enable/disenable of the scan chains 11 and 21 individually is not required.

Note that in this embodiment, it is explained that there is only one scan chain 30, however it is needless to say that there may be a plurality of scan chains. Further, there may be a plurality of memory BIST circuits. In such case as well, a scan chain included in the memory BIST circuits may be disposed to an output side of each scan chain.

In this embodiment, by disposing the scan chain 21 of the memory BIST circuit 20, it is possible to perform a scan test in the user logic circuit 10 even when the scan chain 21 included in the memory BIST circuit 20 is disenabled. Further, in parallel with this, a BIST for a memory by the memory BIST circuit 20 can be performed. Using this, at a burn-in, by applying stress to the user logic circuit 10 and applying stress to the memory 40 by a BIST of the memory BIST circuit 20, it is possible to perform a burn-in test at the same time for the user logic circuit 10 and the memory 40.

It is apparent that the present invention is not limited to the above embodiment and it may be modified and changed without departing from the scope and spirit of the invention.

What is claimed is:

1. A semiconductor integrated circuit comprising:
a logic circuit unit having a logic circuit and a first scan chain to perform a scan chain for the logic circuit; and
a memory unit having a memory, a self-checking circuit for the memory, and a second scan chain to perform a scan test for the self-checking circuit,
wherein a scan chain is formed by the first and the second scan chains, and the second scan chain is disposed in an output side of the scan chain, and
along with setting the first scan chain to enable according to one or a plurality of control signals, the second scan chain set to disenable.

2. The semiconductor integrated circuit according to claim 1, wherein along with setting the first scan chain to enable according to a first scan enable signal that sets the first scan chain to a scan mode, the second scan chain is set to disenable according to a second scan enable signal that sets the second scan chain to the scan mode.

3. The semiconductor integrated circuit according to claim 1, further comprising:
a control circuit to control the scan mode of the second scan chain according to a first scan enable signal,
wherein along with setting the first scan chain to enable according to the first scan enable signal, the second scan chain is set to disenable by the control circuit.

4. The semiconductor integrated circuit according to claim 3, wherein the control circuit controls the scan mode of the second scan chain according to the first scan enable signal and a burn-in test mode signal that sets to a burn-in test mode.

5. The semiconductor integrated circuit according to claim 3, wherein the control circuit controls the scan mode of the second scan chain according to the first scan enable signal and a memory test start signal that starts a test for the memory by the self-checking circuit.

6. A method to test a semiconductor integrated circuit that performs a burn-in test at the same time to a logic circuit and a memory, the method comprising:
setting a first scan chain that performs a scan test for the logic circuit to enable, and setting a second scan chain of a memory self-checking circuit to enable, the memory self-checking circuit being possible to be scan tested by the second scan chain that is disposed to an output side of the first scan chain;
performing a burn-in test by giving stress to the logic circuit according to the first chain in parallel with giving stress to the memory by performing a test for the memory by the memory self-checking circuit.

7. The method according to claim 6, further comprising:
setting the first scan chain to enable according to a first scan enable signal, and setting the second scan chain to disenable according to a second scan enable signal.

8. The method according to claim 6, further comprising:
setting the second scan chain to disenable by a control circuit that controls a scan mode of the second scan chain according to a first scan enable signal along with setting the first scan chain to enable according to the first scan enable signal.

9. The semiconductor integrated circuit according to claim 7, further comprising:
controlling the scan mode of the second scan chain according to the first scan enable signal and a burn-in test mode that sets to a burn-in test mode.

10. The semiconductor integrated circuit according to claim 7, further comprising:
controlling the scan mode of the second scan chain according to the first scan enable signal and a memory test start signal that starts the test for the memory by the self-checking circuit.
